(19) United States
(12) Patent Application Publication
(10) Pub. No.: US 2015/0179815 A1
(43) Pub. Date: Jun. 25, 2015

(54) Quantum Well IGZO Devices and Methods for Forming the Same

(71) Applicant: Intermolecular, Inc., San Jose, CA (US)

(72) Inventor: Khaled Ahmed, Anaheim, CA (US)

(73) Assignee: Intermolecular, Inc., San Jose, CA (US)

(21) Appl. No.: 14/135,521

(22) Filed: Dec. 19, 2013

(51) Int. Cl. H01L 29/786; H01L 29/15; H01L 29/66

(52) U.S. Cl. CPC H01L 29/78696; H01L 29/66969; H01L 29/7869; H01L 29/78693; H01L 29/151

(57) ABSTRACT

Embodiments described herein provide indium-gallium-zinc oxide (IGZO) devices, such as IGZO thin-film transistors (TFTs), and methods for forming such devices. A substrate is provided. A gate electrode is formed above the substrate. An IGZO channel layer is formed above the gate electrode. The IGZO channel layer has a first sub-layer including crystalline IGZO, a second sub-layer including amorphous IGZO, and a third sub-layer including magnesium and zinc. A source electrode and a drain electrode are formed above the IGZO channel layer.

### TECHNICAL FIELD

The present invention relates to indium-gallium-zinc oxide (IGZO) devices. More particularly, this invention relates to quantum well IGZO devices, such as thin-film transistors (TFTs), and methods for forming such devices.

### BACKGROUND OF THE INVENTION

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light display applications. Due to these attributes, IGZO TFTs may even be favored over low cost amorphous silicon TFTs and relatively high mobility polycrystalline silicon TFT for display device applications.

IGZO devices typically utilize amorphous IGZO (a-IGZO) within the channel (or channel layer). Recent developments in the field suggest that the use of crystalline IGZO may provide improved electrical and chemical stability in certain conditions. However, when either a-IGZO or c-IGZO is used as the channel layer, electrons must move between the channel layer and the source and drain electrodes, and electron mobility is generally limited to less than 30 cm²/Vs. The same is true for other types of TFTs, such as those utilizing amorphous silicon.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with a first indium-gallium-zinc oxide (IGZO) layer formed above the gate dielectric layer.

FIG. 4 is a cross-sectional view of the substrate of FIG. 3 with a second IGZO layer formed above the first IGZO layer.

FIG. 5 is a cross-sectional view of the substrate of FIG. 4 with a contact layer formed above the second IGZO layer.

FIG. 6 is a cross-sectional view of the substrate of FIG. 5 with an IGZO channel layer formed above the gate dielectric layer.

FIG. 7 is a cross-sectional view of the substrate of FIG. 6 with source and drain electrodes formed above the IGZO channel layer.

FIG. 8 is a cross-sectional view of the substrate of FIG. 7 with a passivation layer formed above the source and drain electrodes.

FIG. 9 is a diagram comparing the energy band gaps of magnesium-zinc oxide, amorphous IGZO, and crystalline IGZO.

FIG. 10 is a simplified cross-sectional diagram of a physical vapor deposition (PVD) tool according to some embodiments.

FIG. 11 is a flow chart illustrating a method for forming IGZO devices according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide cost effective, high performance thin-film transistors (TFTs) (e.g., for display applications) and methods for forming such TFTs. In particular, cost effective, high performance indium-gallium-zinc oxide (IGZO) TFTs and methods for forming such IGZO TFTs are provided. In some embodiments, this is accomplished by forming a two-dimensional electron gas (2DEG), along with a quantum well, within (or at) the channel (or channel layer) of the devices. The 2DEG may be formed without intentionally doping any of the materials in the channel, thereby mitigating the deleterious effect of ionized impurity scattering. The resulting TFTs (or the channels thereof) may have a very high electron mobility (e.g., greater than 1000 cm²/Vs).

In some embodiments, the channel is formed as a composite IGZO channel with three sub-layers (i.e., a tri-layer IGZO channel). The first sub-layer may include crystalline IGZO (c-IGZO). The second sub-layer may include amorphous IGZO (a-IGZO). The third sub-layer may include magnesium and zinc. In some embodiments, the third sub-layer is made of magnesium-zinc oxide. The third sub-layer may be formed between the second sub-layer and the source and drain electrodes. The second sub-layer may be formed above the first sub-layer.

In some embodiments, the first sub-layer of the IGZO channel is formed by depositing (e.g., using physical vapor deposition (PVD)) IGZO. The crystalline structure of the IGZO may be enhanced by forming the IGZO using particular processing conditions and/or during an annealing process. After the crystalline IGZO (or c-IGZO) is formed, a thin layer (e.g., 3-15 nm) of IGZO is formed above in such a way that it remains substantially amorphous (e.g., it is deposited after the annealing process). This thin layer of a-IGZO forms the second sub-layer. The third sub-layer may then be deposited above the second sub-layer (e.g., using PVD).

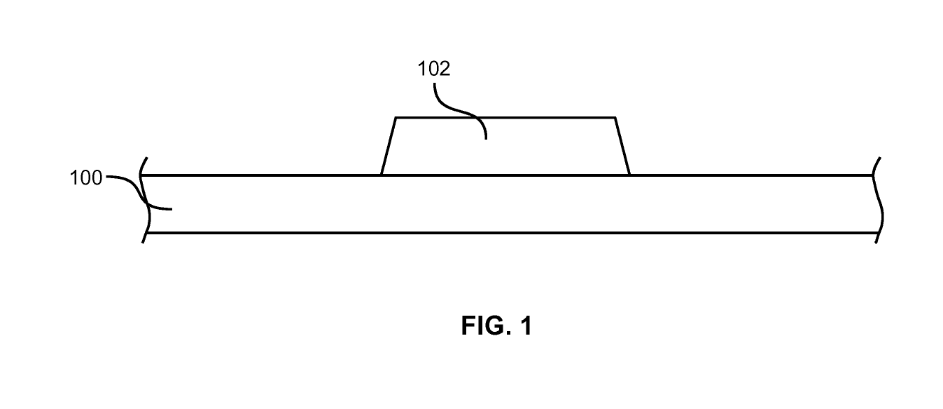

FIGS. 1-8 illustrate a method for forming an IGZO TFT (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between about 0.01 centimeters (cm) and about 0.5 cm. Although only a portion of the substrate 100 is shown, it should be understood that the substrate 100 may have a width of, for example, between about 5.0 cm and about 4.0 meters (m). Although not shown, in some embodiments, the substrate 100 may have a dielectric layer (e.g., silicon oxide) formed above an upper surface thereof. In such embodiments, the components described below are formed above the dielectric layer. Also, in some embodiments, the substrate 100 is at least partially made of a of a semiconductor material (e.g., silicon, germanium, gallium arsenide, etc.). For example, in some embodiments, the substrate includes glass with a layer of semiconductor material formed thereon. Before any of the components described below are formed above the substrate 100 (e.g., an upper surface thereof) may be cleaned using, for example, wet and/or dry cleaning processes, as is commonly understood.

Still referring to FIG. 1, a gate electrode 102 is formed above the substrate 100. In some embodiments, the gate electrode 102 is made of a conductive material, such as copper, silver, aluminum, manganese, molybdenum, or a combination thereof. The gate electrode may have a thickness of, for example, between about 20 nm and about 500 nm. Although not shown, it should be understood that in some embodiments, a seed layer (e.g., a copper alloy) is formed between the substrate 100 and the gate electrode 102.

It should be understood that the various components above the substrate 100, such as the gate electrode 102 and those described below, are formed using processing techniques suitable for the particular materials being deposited, such as physical vapor deposition (PVD) (e.g., co-sputtering in some embodiments), chemical vapor deposition (CVD), plasma-enhanced (PECVD), electroplating, etc. Furthermore, although not specifically shown in the figures, it should be understood that the various components formed above the substrate 100, such as the gate electrode 102, may be sized and shaped using a photolithography process and an etching process, as is commonly understood, such that the components are formed above selected regions of the substrate 100.

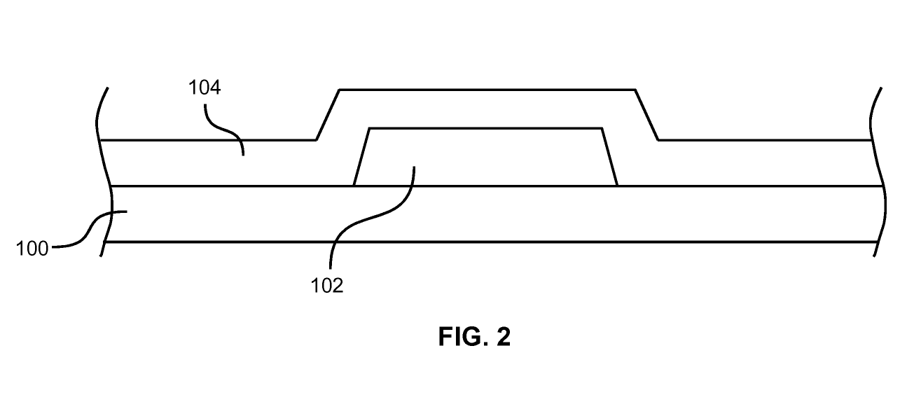

Referring to FIG. 2, a gate dielectric layer 104 is then formed above the gate electrode 102 and the exposed portions of the substrate 100. The gate dielectric layer 104 may be made of, for example, silicon oxide, silicon nitride, or a high-k dielectric (e.g., having a dielectric constant greater than 3.9), such as zirconium oxide, hafnium oxide, or aluminum oxide. In some embodiments, the gate dielectric layer 104 has a thickness of, for example, between about 10 nm and about 500 nm.

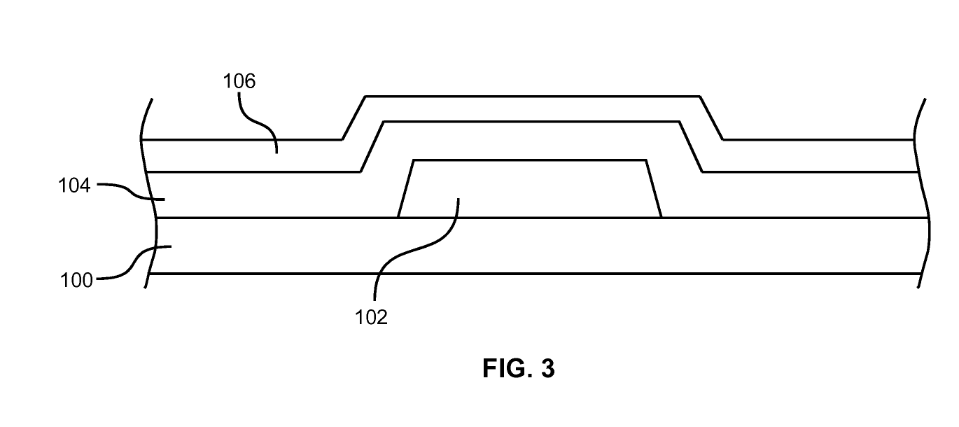

As shown in FIG. 3, a first (or lower) IGZO layer 106 is then formed above the gate dielectric layer 104. The first IGZO layer 106 may be made of IGZO in which a ratio of the respective elements is, for example, 1:1:1:1-3. In some embodiments, the IGZO within the first IGZO layer 106 is deposited as amorphous IGZO (a-IGZO). However, in some embodiments, the IGZO is formed or deposited using processing conditions to enhance the crystalline structure thereof. In some embodiments, the first IGZO layer 106 is formed using PVD. The IGZO may be deposited from a single target that includes indium, gallium, and zinc (e.g., an indium-gallium-zinc alloy target or an IGZO target), but two or more targets may also used (e.g., co-sputtering with an indium-zinc target and a gallium target). The first IGZO layer 106 may have a thickness of, for example, between about 30 nm and about 100 nm, such as about 50 nm.

Although not specifically shown, in some embodiments, the first IGZO layer 106 (and the other components shown in FIG. 3) may then undergo an annealing process. In some embodiments, the annealing process includes a relatively low temperature (e.g., less than about 600° C., preferably less than about 450° C.) heating process in, for example, an ambient gaseous environment (e.g., nitrogen, oxygen, or ambient/air) to (further) enhance the crystalline structure of the IGZO. The heating process may occur for between about 1 minute and about 200 minutes. After the annealing (or heating) process, the first IGZO layer 106 may (substantially) include crystalline IGZO (c-IGZO). As used herein a “crystalline” material (e.g., c-IGZO) may be considered to be one that is more than 30% crystalline by volume, as determined by a technique such as X-ray Diffraction (XRD). In some embodiments, the c-IGZO is c-axis aligned crystal (CAAC) IGZO, as is commonly understood.

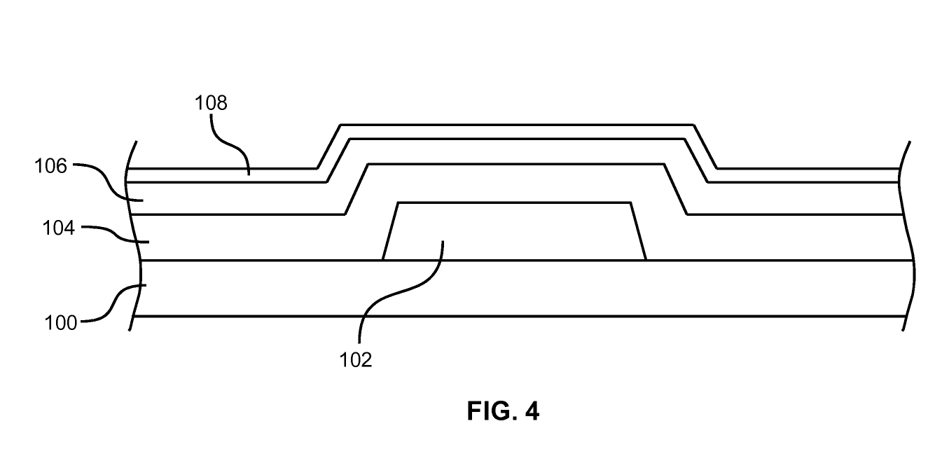

Referring to FIG. 4, a second (or upper) IGZO layer 108 is then formed above the first IGZO layer 106. The second IGZO layer 108 may be made of IGZO in which a ratio of the respective elements is, for example, 1:1:1:1-3. In some embodiments, the IGZO within the second IGZO layer 108 is deposited in such a way that it is substantially amorphous (i.e., a-IGZO). For example, in some embodiments, the second IGZO layer 108 is formed using PVD in a gaseous environment for, for example, argon and oxygen. The second IGZO layer 108 may have a thickness of, for example, between about 3 nm and about 15 nm, preferably between about 5 nm and about 10 nm.

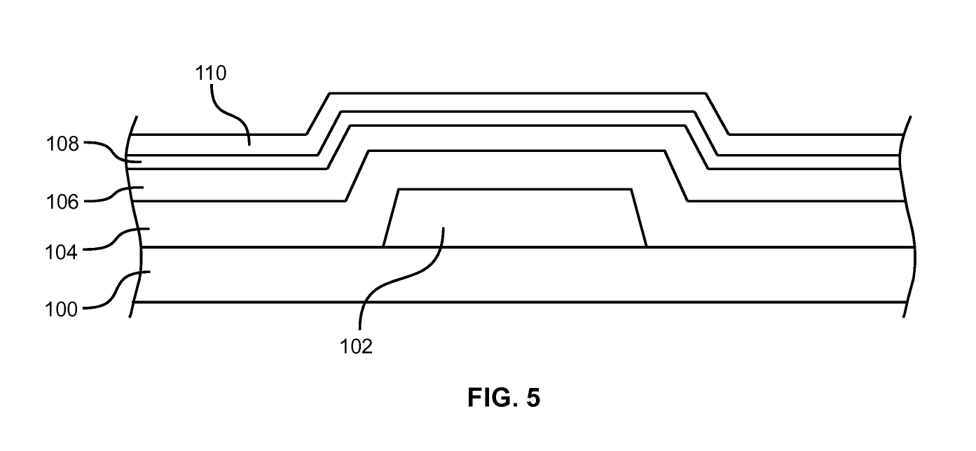

As shown in FIG. 5, a contact layer 110 is then formed above the second IGZO layer 108. In some embodiments, the contact layer 110 includes magnesium and zinc. The contact layer 110 may include (or be made of) magnesium-zinc oxide. In some embodiments, the contact layer 110 is made of magnesium-zinc oxide that is about 15% by weight magnesium. The contact layer 110 may be formed using PVD. In some embodiments, the contact layer 110 is formed using PVD performed at a processing temperature near room temperature (e.g., 20-25° C.). In some embodiments, the contact layer 110 has a thickness of, for example, between about 20 nm and about 50 nm.

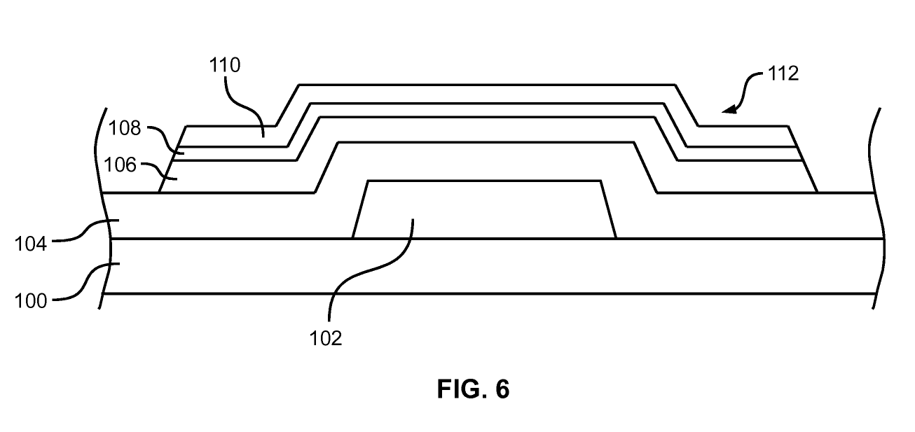

Referring to FIG. 6, the first IGZO layer 106, the second IGZO layer 108, and the contact layer 110 are then patterned (e.g., etched) to form an IGZO channel (or channel layer) 112 above the gate dielectric layer 104, over the gate electrode 102. In some embodiments, layers 106, 108, and 110 are etched using the same etching process. In some embodiments, the contact layer 110 is etched using an etching process different than that of the first and second IGZO layers 106 and 108. After the etching process, the first IGZO 106 may form a first sub-layer of the IGZO channel layer 112, the second IGZO layer 108 may form a second sub-layer of the IGZO channel layer 112, and the contact layer 110 may form a third sub-layer of the IGZO channel layer 112. That is, the IGZO channel layer 112 may be considered to be a composite or tri-layer IGZO channel layer, with each of the sub-layers thereof being made of different materials.

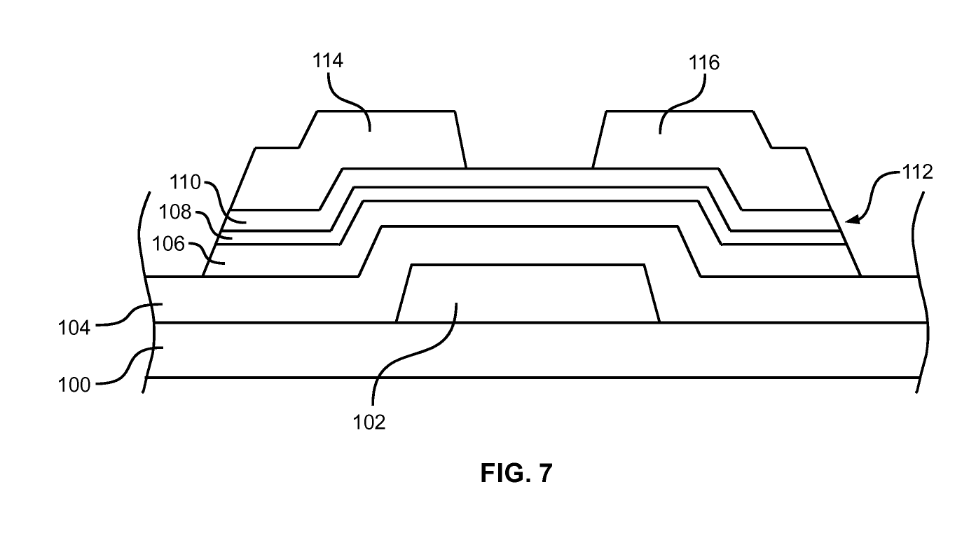

Referring now to FIG. 7, a source electrode (or region) 114 and a drain electrode (or region) 116 are then formed above the IGZO channel layer 112. As shown, the source electrode 114 and the drain electrode 116 lie on ends of the IGZO channel layer 112. As will be appreciated by one skilled in the art, the source electrode 114 and the drain electrode 116 may be defined as shown in FIG. 7 using a “back-channel etch” (BCE) process to, for example, form the gap between the source electrode 114 and the drain electrode 116, which is vertically aligned with the gate electrode 102. However, in some embodiments, an etch-stop layer, as is commonly understood, may be formed above the IGZO channel layer 112 to facilitate the defining of the source electrode 114 and the drain electrode 116 (e.g., by protecting the IGZO during the etch process).

In some embodiments, the source electrode 114 and the drain electrode 116 are made of titanium, aluminum, molybdenum, copper, copper-manganese alloy, or a combination thereof. In some embodiments, the source electrode 114 and the drain electrode 116 include multiple sub-layers (e.g., sub-layers of titanium and titanium nitride). The source electrode 114 and the drain electrode 116 may have a thickness of, for example, between about 20 nm and 500 nm.

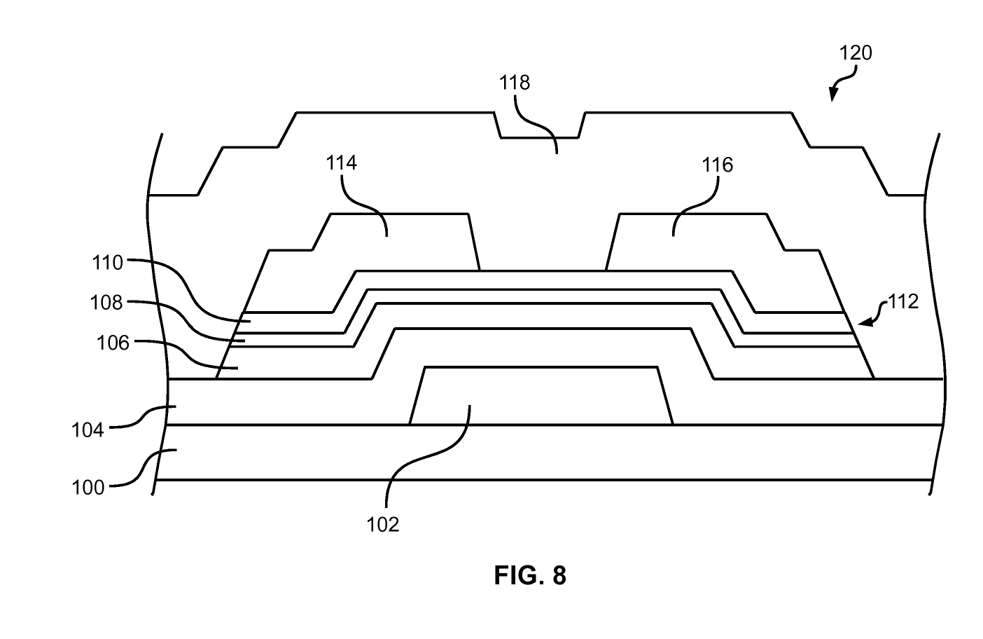

Referring to FIG. 8, a passivation layer 118 is then formed above the source electrode 114, the drain electrode 116, and the exposed portions of the gate dielectric layer 104 and the IGZO channel layer 112. In some embodiments, the passivation layer 118 is made of silicon oxide, silicon nitride, aluminum oxide, aluminum nitride, or a combination thereof and has a thickness of, for example, between about 0.1 micrometers (μm) and about 1.5 μm.

The deposition of the passivation layer 118 may substantially complete the formation of an IGZO device 120, such as an inverted, staggered bottom-gate IGZO TFT. It should be understood that although only a single device 120 is shown as being formed on a particular portion of the substrate 100 in FIGS. 1-8, the manufacturing processes described above may be simultaneously performed on multiple portions of the substrate 100 such that multiple devices 120 are simultaneously formed, as is commonly understood. Further, although not shown, in some embodiments, such as those intended for use in display applications, pixel electrodes may also be formed above the substrate 100 during the formation of the IGZO device(s) 120. The pixel electrodes may be made of a transparent conductive material, such as indium-tin oxide (ITO).

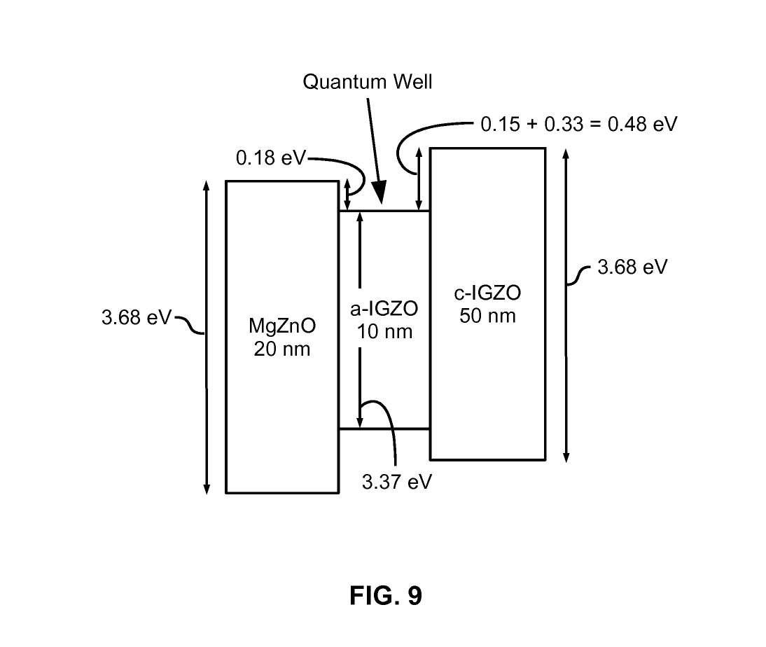

FIG. 9 is a diagram depicting the energy band gaps of, and band offsets between, magnesium-zinc oxide (e.g., 15% magnesium by weight), a-IGZO, and c-IGZO. In the samples depicted in FIG. 9, the magnesium-zinc oxide has a thickness of about 20 nm, the a-IGZO has a thickness of about 10 nm, and the c-IGZO has a thickness of about 50 nm. As shown, the energy band gaps (E_{g}) of magnesium-zinc oxide and c-IGZO are the same (i.e., 3.68 eV) and are offset from the energy band gap of a-IGZO substantially equal amounts, but with opposing polarities. Due to this polarization mismatch, a 2DEG is formed between the magnesium-zinc oxide and the a-IGZO, and a quantum well is formed within (or by) the a-IGZO between the magnesium-zinc oxide and the c-IGZO. During operation, electrons are confined within the quantum well, as will be appreciated by one skilled in the art.

As a result of utilizing the quantum well described above, high performance devices are provided, which may have an electron mobility of, for example, greater than 1000 cm²/Vs. In comparison, amorphous silicon TFTs typically have an electron mobility of less than about 0.5 cm²/Vs, and conventional a-IGZO TFTs typically have an electron mobility of less than about 12 cm²/Vs. Additionally, the devices described herein may be formed using known, well-developed processing techniques (e.g., forming a-IGZO using PVD, etc.). As a result, the devices may be readily manufacturing, without any significant increases in manufacturing costs.

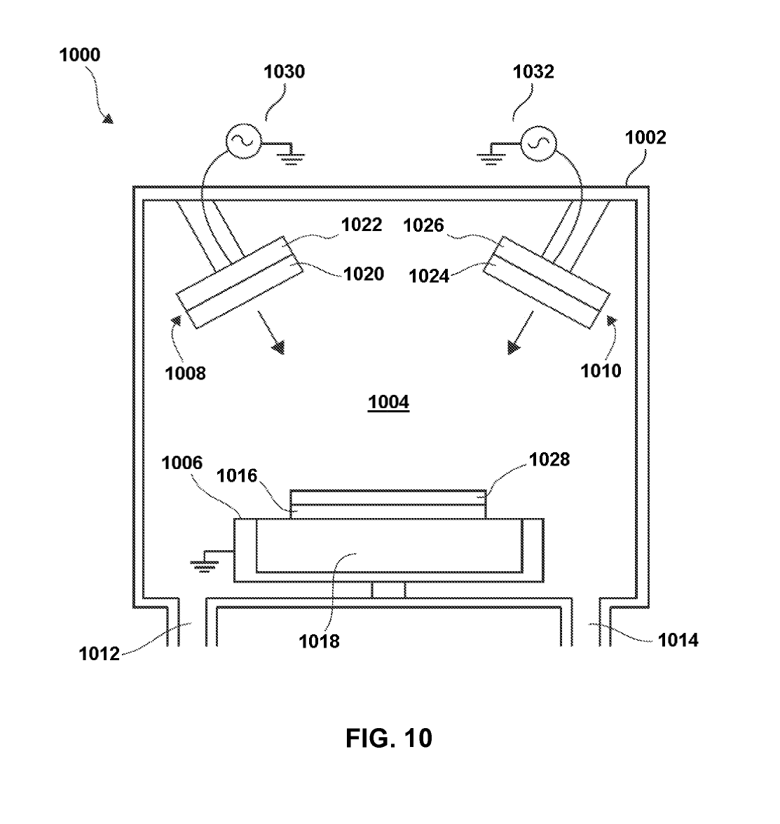

FIG. 10 provides a simplified illustration of a physical vapor deposition (PVD) tool (and/or system) 1000 which may be used, in some embodiments, to form some of the components of the IGZO devices described above. The PVD tool 1000 shown in FIG. 10 includes a housing 1002 that defines, or encloses, a processing chamber 1004, a substrate support 1006, a first target assembly 1008, and a second target assembly 1010.

The housing 1002 includes a gas inlet 1012 and a gas outlet 1014 near a lower region thereof on opposing sides of the substrate support 1006. The substrate support 1006 is positioned near the lower region of the housing 1002 and in configured to support a substrate 1016. The substrate 1016 may be a round substrate having a diameter of, for example, about 200 mm or about 300 mm. In other embodiments (such as in a manufacturing environment), the substrate 1016 may have other shapes, such as square or rectangular, and may be significantly larger (e.g., about 0.5 m to about 4 m across). The substrate support 1006 includes a support electrode 1018 and is held at ground potential during processing, as indicated.

The first and second target assemblies (or process heads) 1008 and 1010 are suspended from an upper region of the housing 1002 within the processing chamber 1004. The first target assembly 1008 includes a first target 1020 and a first target electrode 1022, and the second target assembly 1010 includes a second target 1024 and a second target electrode 1026. As shown, the first target 1020 and the second target 1024 are oriented or directed towards the substrate 1016. As is commonly understood, the first target 1020 and the second target 1024 include one or more materials that are to be used to deposit a layer of material 1028 on the upper surface of the substrate 1016.

The materials used in the targets 1020 and 1024 may, for example, include indium, gallium, zinc, tin, silicon, silver, aluminum, magnesium, manganese, molybdenum, zirconium, hafnium, titanium, copper, or any combination thereof (i.e., a single target may be made of an alloy of several metals). In some embodiments, the materials used in the targets may include oxygen, nitrogen, or a combination of oxygen and nitrogen in order to form oxides, nitrides, and oxynitrides. Additionally, although only two targets 1020 and 1024 are shown, additional targets may be used.

The PVD tool 1000 also includes a first power supply 1030 coupled to the first target electrode 1022 and a second power supply 1032 coupled to the second target electrode 1024. As is commonly understood, in some embodiments, the power supplies 1030 and 1032 pulse direct current (DC) power to the respective electrodes, causing material to be, at least in some embodiments, simultaneously sputtered (i.e., co-sputtered) from the first and second targets 1020 and 1024. In some embodiments, the power is alternating current (AC) to assist in directing the ejected material towards the substrate 1016.

During sputtering, inert gases (or a plasma species), such as argon or krypton, may be introduced into the processing chamber 1004 through the gas inlet 1012, while a vacuum is applied to the gas outlet 1014. The inert gas(es) may be used to impact the targets 1020 and 1024 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 10, the PVD tool 1000 may also include a control system having, for example, a processor and a memory, which is in operable communication with the other components shown in FIG. 10 and configured to control the operation thereof in order to perform the methods described herein.

Although the PVD tool 1000 shown in FIG. 10 includes a stationary substrate support 1006, it should be understood that in a manufacturing environment, the substrate 1016 may be in motion (e.g., an in-line configuration) during the formation of various layers described herein.

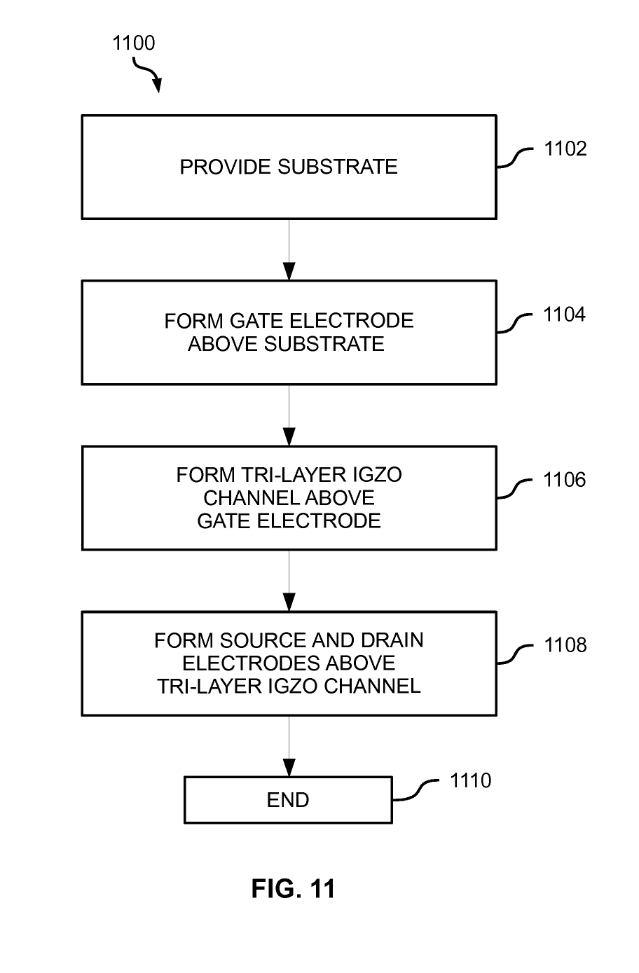

FIG. 11 illustrates a method 1100 for forming IGZO devices, such as IGZO TFTs, according to some embodiments. At block 1102, the method 1100 begins with a substrate being provided. As described above, in some embodiments, the substrate includes glass, a semiconductor material, or a combination thereof.

At block 1104, a gate electrode is formed above the substrate. The gate electrode may be made of a conductive material, such as copper, silver, aluminum, manganese, molybdenum, or a combination thereof.

At block 1106, a tri-layer IGZO channel (or channel layer) is formed above the gate electrode. As described above, in some embodiments, the IGZO channel layer includes a first sub-layer including c-IGZO, a second sub-layer including a-IGZO, and a third sub-layer including magnesium-zinc oxide.

At block 1108, a source electrode and a drain electrode are formed above the tri-layer IGZO channel layer. The source and drain electrodes may made of, for example, titanium, aluminum, molybdenum, copper, copper-manganese alloy, or a combination thereof.

Although not shown, in some embodiments, the method 1100 includes the formation of additional components of an IGZO device, such as a gate dielectric layer and a passivation layer, as well as additional processing steps, such as an annealing process. At block 1110, the method 1100 ends.

Thus, in some embodiments, methods for forming an IGZO device are provided. A substrate is provided. A gate electrode is formed above the substrate. An IGZO channel layer is formed above the gate electrode. The IGZO channel layer has a first sub-layer including crystalline IGZO, a second sub-layer including amorphous IGZO, and a third sub-layer including magnesium and zinc. A source electrode and a drain electrode are formed above the IGZO channel layer.

In some embodiments, methods for forming an IGZO device are provided. A substrate is provided. A gate electrode is formed above the substrate. A gate dielectric layer is formed above the gate electrode. An IGZO channel layer is formed above the gate dielectric layer. The IGZO channel layer has a first sub-layer including crystalline IGZO, a second sub-layer including amorphous IGZO, and a third sub-layer including magnesium-zinc oxide. A source electrode and a drain electrode formed above the IGZO channel layer.

In some embodiments, IGZO devices are provided. Each IGZO device includes a substrate. A gate electrode is formed above the substrate. An IGZO channel layer is formed above the gate electrode. The IGZO channel layer has a first sub-layer including crystalline IGZO, a second sub-layer including amorphous IGZO, and a third sub-layer including magnesium-zinc oxide. A source electrode and a drain electrode are formed above the IGZO channel layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming an indium-gallium-zinc oxide (IGZO) device, the method comprising:
providing a substrate;
forming a gate electrode above the substrate;
forming a first sub-layer above the gate electrode, wherein the first sub-layer comprises crystalline IGZO;
forming a second sub-layer above the first sub-layer, wherein the second sub-layer comprises amorphous IGZO;
forming a third sub-layer above the second sub-layer, wherein the third sub-layer comprises magnesium and zinc; and
forming a source electrode and a drain electrode above the third sub-layer.

2. The method of claim 1, wherein the third sub-layer of the IGZO channel layer comprises magnesium-zinc oxide.

3. The method of claim 1, wherein the third sub-layer has a thickness of between about 20 nanometers (nm) and about 50 nm.

4. The method of claim 1, wherein the second sub-layer has a thickness of between about 3 nm and about 15 nm.

5. The method of claim 1, wherein the first sub-layer has a thickness of between about 30 nm and about 100 nm.

6. The method of claim 1, further comprising:
heating the first sub-layer.

7. The method of claim 6, further comprising forming the second sub-layer and the third sub-layer after the heating of the first sub-layer.

8. The method of claim 1, further comprising:
forming a gate dielectric layer above the gate electrode, wherein the first sub-layer is formed above the gate dielectric layer; and
forming a passivation layer above the source electrode and the drain electrode.

9. A method for forming an indium-gallium-zinc oxide (IGZO) device, the method comprising:
providing a substrate;
forming a gate electrode above the substrate;
forming a gate dielectric layer above the gate electrode;
forming a first sub-layer above the gate electrode, wherein the first sub-layer comprises crystalline IGZO;
forming a second sub-layer above the first sub-layer, wherein the second sub-layer comprises amorphous IGZO;
forming a third sub-layer above the second sub-layer, wherein the third sub-layer comprises magnesium and zinc; and
forming a source electrode and a drain electrode above the third sub-layer.

10. The method of claim 9, wherein the third sub-layer has a thickness of between about 20 nanometers (nm) and about 50 nm.

11. The method of claim 9, wherein the second sub-layer has a thickness of between about 3 nm and about 15 nm.

12. The method of claim 9, further comprising:
heating the first sub-layer; and
forming the second sub-layer and forming the third sub-layer after the heating of the first sub-layer.

13. The method of claim 9, wherein the third sub-layer of the IGZO channel layer comprises magnesium-zinc oxide.

14. An indium-gallium-zinc oxide (IGZO) device comprising:
a substrate;
a gate electrode above the substrate;
a first sub-layer above the gate electrode, wherein the first sub-layer comprises crystalline IGZO;
a second sub-layer above the first sub-layer, wherein the second sub-layer comprises amorphous IGZO;
a third sub-layer above the second sub-layer, wherein the third sub-layer comprises magnesium and zinc; and
a source electrode and a drain electrode above the third sub-layer.

15. The IGZO device of claim 14, wherein the third sub-layer has a thickness of between about 20 nanometers (nm) and about 50 nm.

16. The IGZO device of claim 14, wherein the second sub-layer has a thickness of between about 3 nm and about 15 nm.

17. The IGZO device of claim 14, wherein the first sub-layer has a thickness of between about 30 nm and about 100 nm.

18. The IGZO device of claim 14, further comprising:
a gate dielectric layer formed above the gate electrode, wherein the first sub-layer is formed above the gate dielectric layer; and
a passivation layer formed above the source electrode and the drain electrode.

19. The method of claim 14, wherein the third sub-layer of the IGZO channel layer comprises magnesium-zinc oxide.
